(19) United States
(12) Patent Application Publication
(10) Pub. No.: US 2019/0115284 A1
(43) Pub. Date: Apr. 18, 2019

(54) COOLING DEVICE AND METHOD FOR HEAT-GENERATING COMPONENTS

(71) Applicant: David Herbert Livingston, Lexington, TN (US)

(72) Inventor: David Herbert Livingston, Lexington, TN (US)

(21) Appl. No.: 16/159,879

(22) Filed: Oct. 15, 2018

Related U.S. Application Data
(60) Provisional application No. 62/572,983, filed on Oct. 16, 2017.

(51) Int. Cl. H01L 23/46; H01C 1/08

(52) U.S. Cl. CPC H01L 23/46; H01C 1/08

(57) ABSTRACT

A cooling device having internal pathways that define separate first and second flow circuits, each configured to direct a coolant at first and second mass flow rates to cool separate first and second surfaces of the cooling device. The internal pathways further define cooling channels into which the first and second flow circuits converge to cool separate third and fourth surfaces of the cooling device. The cooling device may be used simultaneously cool multiple electronic components that have similar or different cooling requirements.

### CROSS REFERENCE TO RELATED APPLICATIONS

This application claims the benefit of U.S. Provisional Application No. 62/572,983 filed Oct. 16, 2017, the contents of which are incorporated herein by reference.

### BACKGROUND OF THE INVENTION

The present invention generally relates to methods and devices for cooling electronic components. This invention particularly relates to a cooling device suitable for simultaneously cooling multiple electronic components.

The challenges of cooling electronic devices have generally increased as electronics have evolved. As manufacturing processes are refined and integrated circuits (ICs) have become faster and more complex, IC devices have become more sophisticated and power-hungry, resulting in higher component temperatures. Consequently, area power densities have increased, resulting in smaller dies dissipating higher thermal loads that may not be adequately addressed by passive heat spreaders and coolers. FIG. 1 schematically represents a thyristor as a nonlimiting example of an IC component that generates considerable heat, and which must be dissipated to ensure acceptable component life. The particular construction depicted in FIG. 1 is a disc, also known as a “hockey puck” design that is commonly used in silicon controlled rectifier (SCR) controllers, particularly in higher current applications.

In view of the above, there is an ongoing desire for improved systems and methods suitable for cooling electronic components.

### BRIEF DESCRIPTION OF THE INVENTION

The present invention provides methods and devices capable of simultaneously cooling multiple electronic components.

According to one aspect of the invention, a cooling device is provided that includes internal pathways that define separate first and second flow circuits, each configured to direct a coolant at first and second mass flow rates to cool separate first and second surfaces of the cooling device. The internal pathways further define cooling channels into which the first and second flow circuits converge to cool separate third and fourth surfaces of the cooling device.

According to another aspect of the invention, a cooling method is provided that includes flowing a coolant through separate first and second flow circuits of a cooling device to direct the coolant at first and second mass flow rates to cool separate first and second surfaces of the cooling device, and converging the first and second flow circuits in cooling channels to cool separate third and fourth surfaces of the cooling device.

Technical effects of the device and method described above preferably include the capability of removing heat from multiple electronic devices using a compact cooling device.

Other aspects and advantages of this invention will be further appreciated from the following detailed description.

### BRIEF DESCRIPTION OF THE DRAWINGS

FIG. 1 schematically represents top and side views of a thyristor.

FIGS. 2A, 2B, 2C, and 2D schematically represent exploded front, front perspective, rear, and rear perspective views, respectively, of a cooling device in accordance with a nonlimiting embodiment of the present invention.

FIG. 3 schematically represents various assembly views of the cooling device of FIGS. 2A-D.

FIG. 4 schematically represents various views of a first cooling plate of the cooling device of FIGS. 2A-D and 3.

FIG. 5 schematically represents various views of a mounting block of the cooling device of FIGS. 2A-D and 3.

FIG. 6 schematically represents various views of a second cooling plate of the cooling device of FIGS. 2A-D and 3.

FIG. 7 schematically represents various views of a cover plate of the cooling device of FIGS. 2A-D and 3.

FIG. 8 schematically represents various views of a third cooling plate of the cooling device of FIGS. 2A-D and 3.

### DETAILED DESCRIPTION OF THE INVENTION

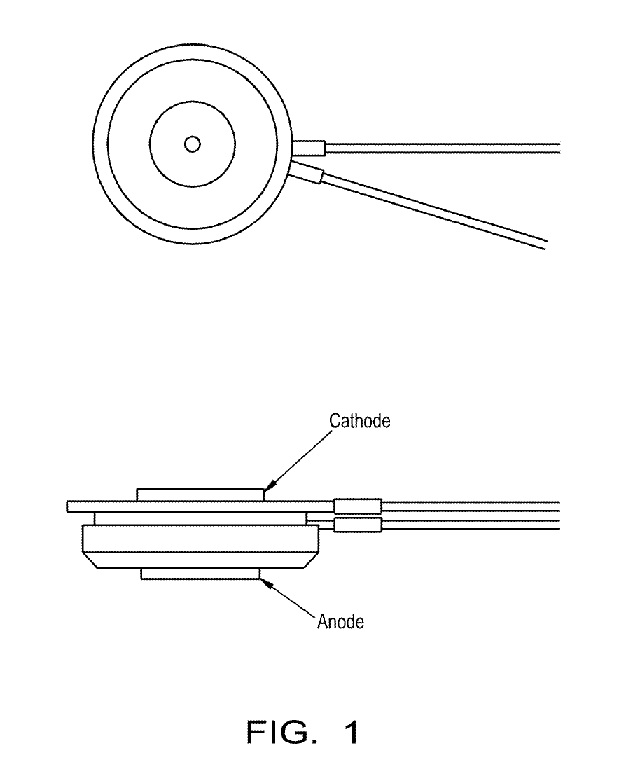

The drawings represent a cooling device 10 configured for cooling multiple heat-generating components, including but not limited to electrical components. The device 10 is particularly well suited for cooling a pair of hockey puck style thyristors (e.g., FIG. 1), as well as resistors used or associated therewith. The cooling device 10 combines the cooling of hockey puck style thyristors and resistors utilizing a network of cooling channels that simultaneously direct a suitable coolant to a pair of surfaces of the device 10 that can be contacted by two different thyristors, and thereafter direct the coolant flow to additional surfaces of the device 10 that can be contacted by one or more resistors.

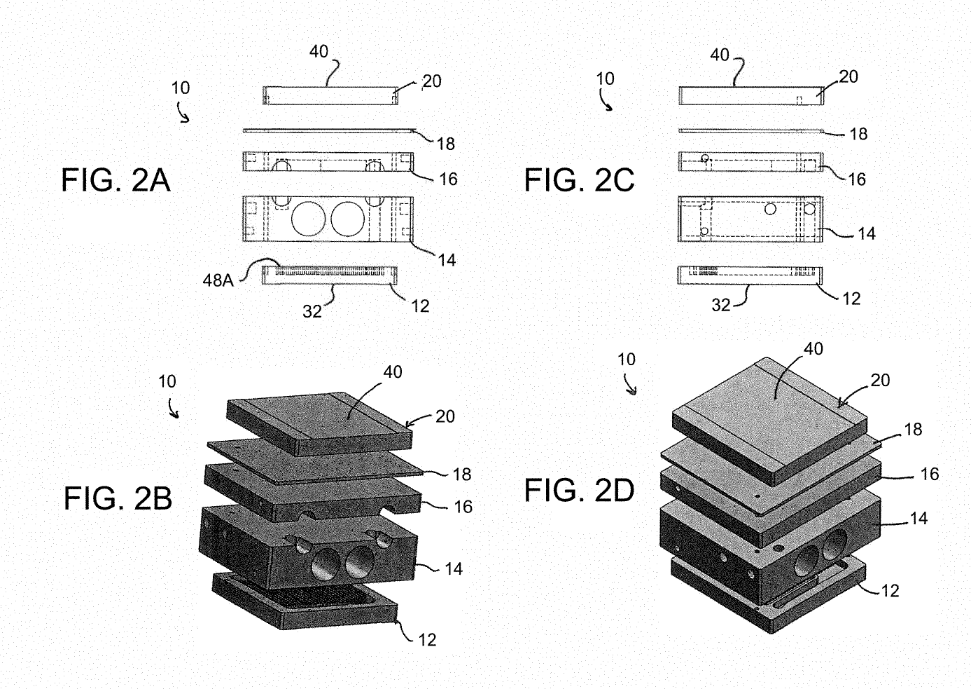

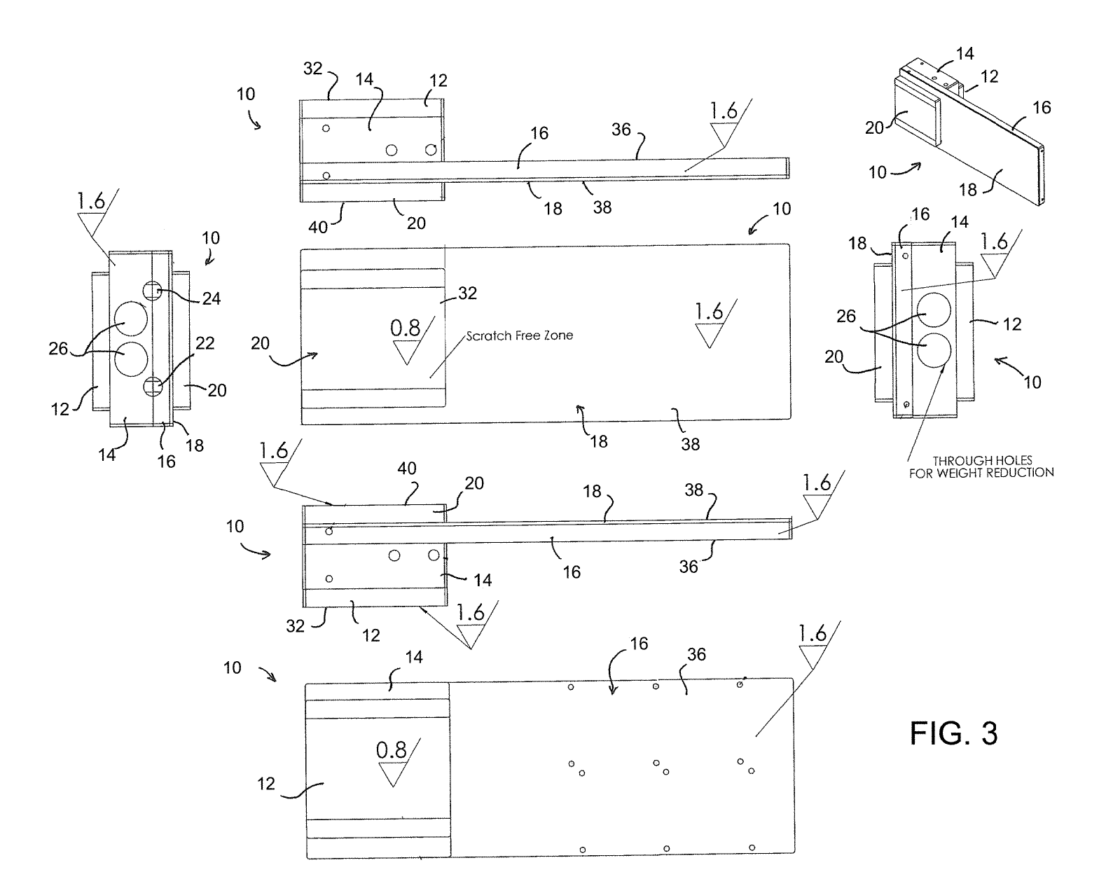

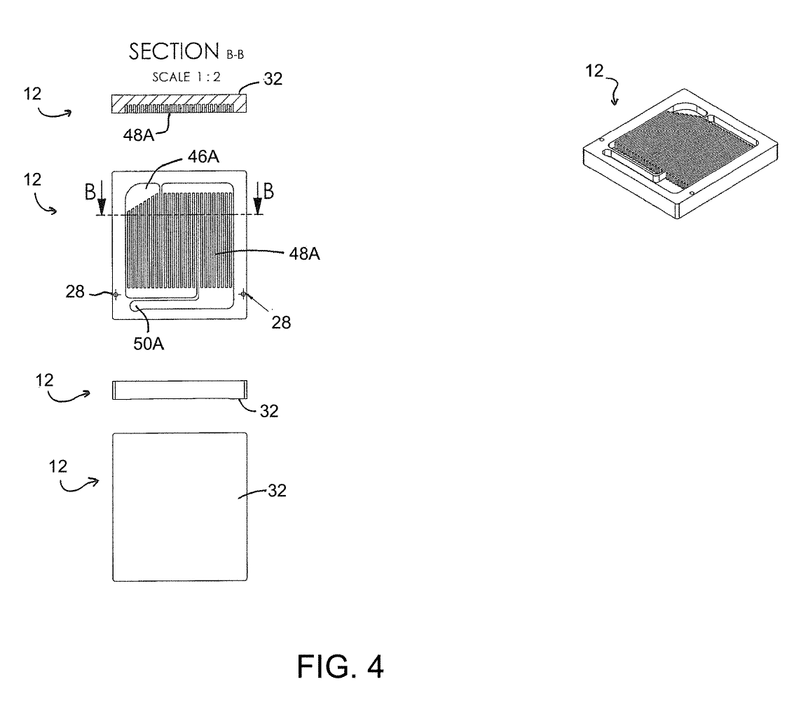

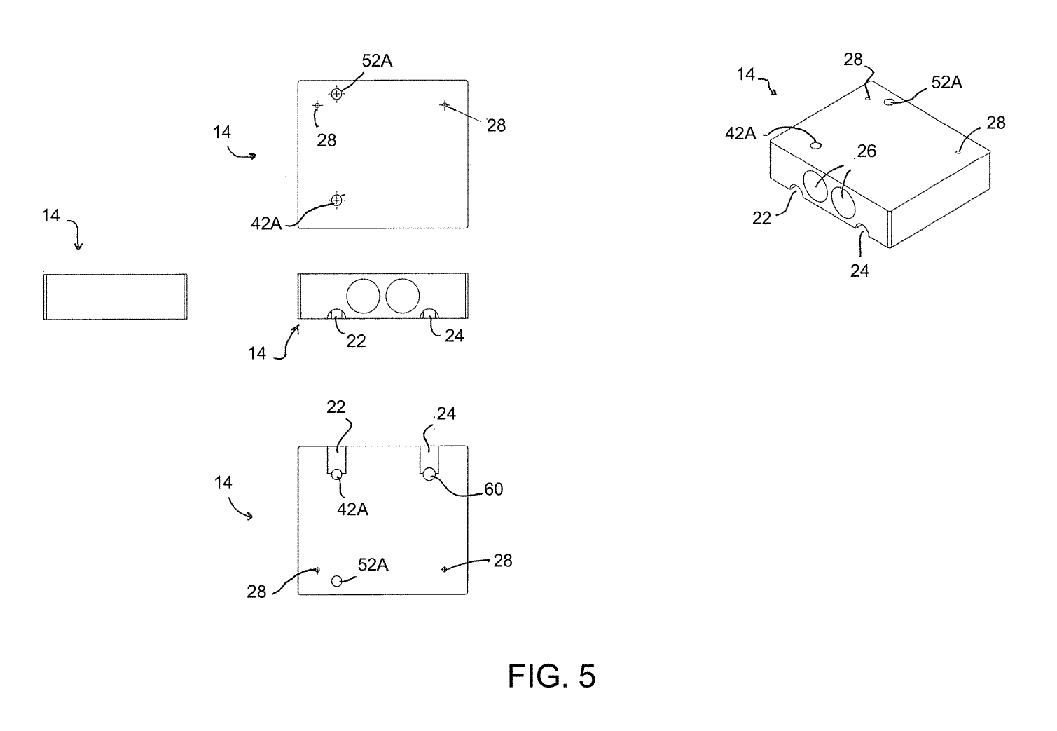

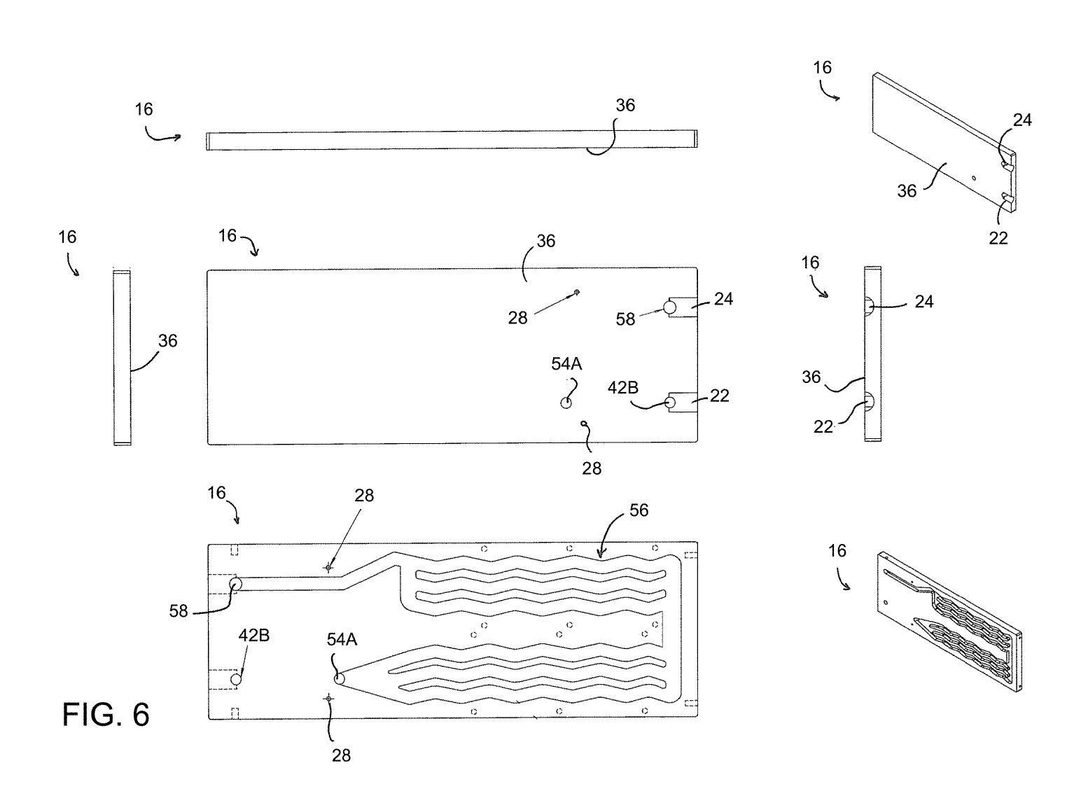

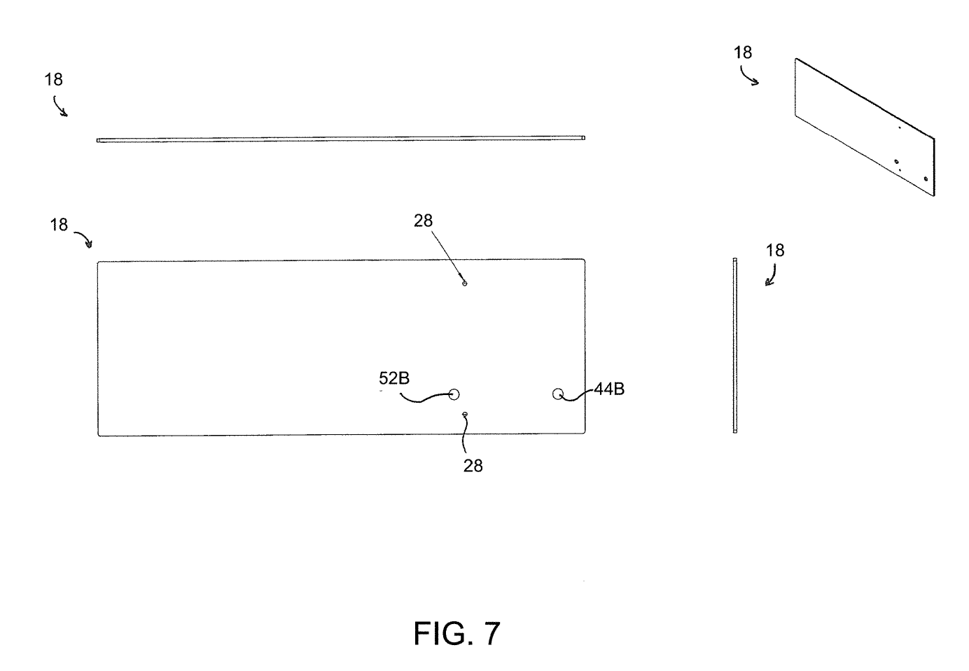

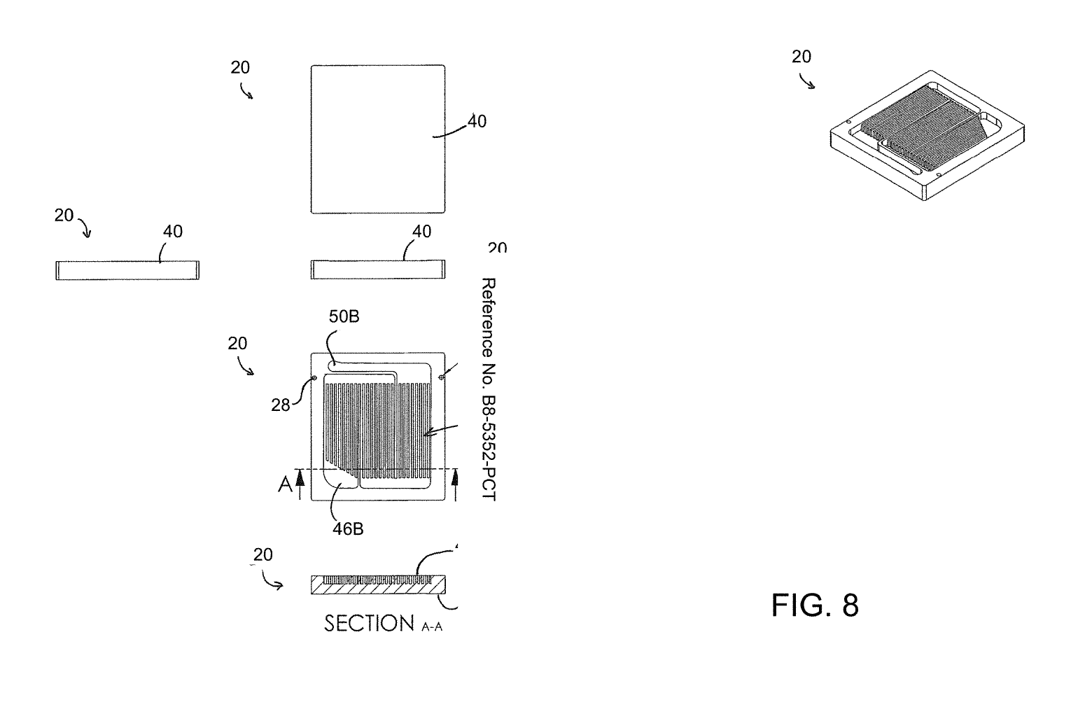

The particular nonlimiting embodiment of the cooling device 10 represented in the drawings is an assembly of components comprising a first cooling plate 12 (FIG. 4), a mounting block 14 (FIG. 5), a second cooling plate 16 (FIG. 6), a cover plate 18 (FIG. 7), and a third cooling plate 20 (FIG. 8). (The second cooling plate 16 and cover plate 18 are not shown in their full lengths in FIGS. 2A-D.) The device 10 and its components may be formed from various materials, nonlimiting examples of which include copper or aluminum. When assembled as shown in FIG. 3, the mounting block 14 and second cooling plate 16 cooperate to define two ports 22 and 24, through which a coolant is able to enter and exit the device 10. Because the device 10 has a preferred (though not required) coolant flow direction, the ports 22 and 24 are designated herein as, respectively, inlet and outlet ports 22 and 24. As a matter of convenience, the portions of the ports 22 and 24 fabricated in the mounting block 14 and second cooling plate 16 are also labeled as 22 and 24. The drawings further represent the device 10 as having two through-holes 26, which are not required for coolant flow, but instead serve to reduce the weight and thermal mass of the device 10. Blind holes 28 are provided in the first cooling plate 12, mounting block 14, second cooling plate 16, cover plate 18, and third cooling plate 20 to facilitate their alignment with pins (not shown) inserted in the holes 28.

The first cooling plate 12, second cooling plate 16, cover plate 18, and third cooling plate 20 define surfaces 32, 36, 38, and 40, respectively, that are adapted for making intimate thermal contact with a heat-generating component. For this purpose, these surfaces 32, 36, 38, and 40 may have surface finishes as indicated in FIG. 3. Any suitable means may be used to ensure that intimate thermal contact can be achieved with heat-generating components. In the particular embodiment of the device 10 represented in the drawings, the surfaces 32 and 40 of the first and third cooling plates 12 and 20 may be configured for individually contacting the anode or cathode of separate thyristors, whereas the surfaces 36 and 38 of the second cooling plate 16 and cover plate 18 may be configured for individually contacting separate sets of resistors.

As noted above, coolant enters the device 10 through its inlet 22, where the coolant flow is divided between a first flow circuit that passes through an inlet channel 42A in the mounting block 14 before entering the first cooling plate 12, and a second flow circuit that passes through an inlet channel 42B in the second cooling plate 16 and then passes through an intermediate channel 44B in the cover plate 18 before entering the third cooling plate 20. Equal coolant flow preferably occurs in the channels 42A and 42B as a result of channels that make up the first and second flow circuits offering substantially equal resistance to flow, for example, based on the cross-sectional areas, lengths, and flow restrictions within the channels. Within the first cooling plate 12, the coolant enters at an inlet cavity 46A, proceeds through serpentine-shaped cooling microchannels 48A, and exits the plate 12 through an outlet cavity 50A. Similarly, within the second cooling plate 20, the coolant enters at an inlet cavity 46B, proceeds through serpentine-shaped cooling microchannels 48B, and exits the plate 20 through an outlet cavity 50B.

The coolant exiting the first cooling plate 12 passes through a series of intermediate channels 52A and 54A within the mounting block 14 and second cooling plate 16, respectively, before entering “zig-zag” cooling channels 56 defined by and between the second cooling plate 16 and cover plate 18. In the nonlimiting example shown in the drawings, the cooling channels 56 are defined in the second cooling plate 16 and closed by the cover plate 18. Similarly, the coolant exiting the third cooling plate 20 passes through an intermediate channel 52B within the cover plate 18 before entering the cooling channels 56. As such, the first and second flow circuits are separately routed through the first and third cooling plates 12 and 20, respectively, before converging at the entrance to the cooling channels 56. FIG. 6 represents the cooling channels 56 as starting at a proximal end of the second cooling plate 16 and extending along the complementary lengths of the second cooling plate 16 and cover plate 18 to a distal end of the second cooling plate 16, before terminating near the proximal end of the cooling plate 16. The coolant exits the cooling channels 56 through a pair of intermediate channels 58 and 60 in the second cooling plate 16 and mounting block 14, respectively, before exiting the cooling device 10 through the exit port 24.

In view of the above, the cooling device 10 provides internal pathways that define two separate flow circuits that are capable of directing a coolant at substantially equal mass flow rates to opposite surfaces 32 and 40 of the device 10, which are cooled as the coolant flows through the microchannels 48A and B of the first and third cooling plates 12 and 20. In this manner, the device 10 can be used to cool the anode side of one thyristor on one side of the device 10, while the opposite side of the device 10 can be used to cool the cathode side of another thyristor. The coolant then flows through internal pathways to the cooling channels 56, where additional heat-generating devices (e.g., resistors) may be mounted for cooling.

If equal mass flow rates through the two separate flow circuits is not desired, the cooling device 10 may be configured to provide internal pathways that are capable of directing a coolant at different mass flow rates to opposite surfaces 32 and 40 of the device 10. This may be achieved as a result of the channels that make up the first and second flow circuits offering different resistance to flow, for example, based on the cross-sectional areas, lengths, and flow restrictions within the channels. As such, the device 10 can be used to concurrently cool multiple electronic devices each having different cooling requirements.

Although the device 10 has been described as having coolant flow into a single inlet port 22, which is then split into two separate flow circuits that converge before exiting through a single outlet port 24, it is foreseeable and within the scope of the invention that the coolant flow may split and converge more than once. For example, the device 10 may include additional components (not shown) wherein the coolant flow is split one or more additional times after converging in the cooling channels 56. In addition, the coolant flow could split within one or both of the microchannels 48A and B and subsequently converge. In this manner, the device 10 may be configured to concurrently cool various electronic devices having different cooling requirements.

While the invention has been described in terms of a specific or particular embodiment, it should be apparent that alternatives could be adopted by one skilled in the art. For example, the cooling device 10 and its components could differ in appearance and construction from the embodiment described herein and shown in the drawing, functions of certain components of the cooling device 10 could be performed by components of different construction but capable of a similar (though not necessarily equivalent) function, various materials could be used in the fabrication of the cooling device 10 and/or its components, and the cooling device 10 could be installed in various types of cooling or electrical systems. In addition, the invention encompasses additional or alternative embodiments in which one or more features or aspects of a particular embodiment could be eliminated. Accordingly, it should be understood that the invention is not necessarily limited to any embodiment described herein or illustrated in the drawing. It should also be understood that the phraseology and terminology employed above are for the purpose of describing the disclosed embodiment, and do not necessarily serve as limitations to the scope of the invention. Therefore, the scope of the invention is to be limited only by the following claims.

1. A cooling device comprising internal pathways that define separate first and second flow circuits, each configured to direct a coolant at first and second mass flow rates to cool separate first and second surfaces of the cooling device, the internal pathways further defining cooling channels into which the first and second flow circuits converge to cool separate third and fourth surfaces of the cooling device.

2. The cooling device of claim 1, wherein the first and second mass flow rates are substantially equal.

3. The cooling device of claim 1, wherein the first and second mass flow rates are unequal.

4. The cooling device of claim 1, wherein the first and second surfaces of the cooling device are configured for making thermal contact with thyristors.

5. The cooling device of claim 1, wherein the third and fourth surfaces of the cooling device are configured for making thermal contact with resistors.

6. The cooling device of claim 1, further comprising first and second sets of serpentine-shaped cooling microchannels adapted for a coolant to flow therethrough to cool the first and second surfaces of the cooling device.

7. The cooling device of claim 1, wherein the first flow circuit comprises cooling channels defined by and between a first cooling plate and a mounting block, the cooling channels are defined by and between a second cooling plate and a cover plate, and the second flow circuit comprises cooling channels defined by and between the cover plate and a third cooling plate.

8. A cooling method comprising:
flowing a coolant through separate first and second flow circuits of a cooling device to direct the coolant at first and second mass flow rates to cool separate first and second surfaces of the cooling device; and
converging the first and second flow circuits in cooling channels to cool separate third and fourth surfaces of the cooling device.

9. The cooling method of claim 8, wherein the first and second mass flow rates are substantially equal.

10. The cooling method of claim 8, wherein the first and second mass flow rates are unequal.

11. The cooling method of claim 8, further comprising providing the cooling device with internal pathways that define the first and second flow circuits and are configured such that the first and second mass flow rates are unequal, wherein the first mass flow rate corresponds to a first cooling requirement of a first electronic component thermally contacting the first surface of the cooling device and the second mass flow rate corresponds to a second cooling requirement of a second electronic component thermally contacting the second surface of the cooling device, wherein the first and second cooling requirements are different.

12. The cooling method of claim 8, further comprising thermally contacting the first and second surfaces of the cooling device with thyristors.

13. The cooling method of claim 8, further comprising thermally contacting the third and fourth surfaces of the cooling device with resistors.

14. The cooling method of claim 8, further comprising flowing the coolant through first and second sets of serpentine-shaped cooling microchannels to cool the first and second surfaces of the cooling device.
